(19) United States
(12) Patent Application Publication
(10) Pub. No.: US 2009/0200607 A1
(43) Pub. Date: Aug. 13, 2009

(54) POWER MOSFET

(75) Inventor: Naoki MATSUURA, Ohtsu-Shi (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/361,067

(22) Filed: Jan. 28, 2009

(30) Foreign Application Priority Data
Feb. 8, 2008 (JP) 2008-028593

(51) Int. Cl. H01L 29/78

(52) U.S. Cl. 257/332; 257/E29.255

(57) ABSTRACT

A power MOSFET of the invention includes a cell region in which a plurality of cells constituted of a transistor having a gate electrode formed in a trench is aligned, the plurality of cells being arranged to form a square grid and a gate interconnect lead formed so as to extend out of the cell region, with an end portion overlapping an outermost peripheral gate electrode in the cell region for connection.

This application is based on Japanese patent application No. 2008-028593, the content of which is incorporated hereinto by reference.

### BACKGROUND

1. Field of the Invention

The present invention relates to a power MOSFET, and more particularly to a power MOSFET that includes a trench gate structure.

2. Related Art

FIGS. 5A to 6B depict a conventional power MOSFET including the trench gate structure.

FIG. 5A is a plan view showing a power MOSFET chip, FIG. 5B is an enlarged fragmentary view thereof, and FIG. 6A is a fragmentary perspective view schematically showing a connection arrangement between gate electrodes and gate interconnect leads. Here, a source electrode, a gate insulating layer and an interlayer dielectric are excluded from FIGS. 5B and 6A.

In FIGS. 5A, 5B and 6A, the numeral 1 designates a power MOSFET chip, 2 a cell constituted of a vertical transistor, 2a an outer peripheral cell, 3 a source electrode, 4 a gate interconnect, 5 a gate bonding pad, 6 a semiconductor substrate, 11 a gate trench, 11a an outermost peripheral gate trench, 14 a gate electrode, 14a an outermost peripheral gate electrode, 15 a gate interconnect lead, 15a a linear lead portion formed in the trench and constituting a part of the gate interconnect lead 15, 15b a loop lead portion formed outside the trench and constituting a part of the gate interconnect lead 15, and E a cell region (region enclosed by dash-dot lines in FIG. 5A).

As shown in FIG. 5A, the power MOSFET chip 1 includes, on its central portion, the cell region E in which a multitude of cells 2, 2a constituted of the vertical transistor is regularly aligned.

All over the cell region E, the source electrode 3 constituted of aluminum or the like, is provided with the intermediation of the interlayer dielectric.

On an outer region of the cell region E (source electrode 3), the gate interconnect 4 constituted of aluminum or the like is provided, so as to surround the cell region E (source electrode 3) with a predetermined spacing therefrom.

The gate interconnect 4 is electrically connected to the gate bonding pad 5 provided at a predetermined position.

A purpose of providing the gate interconnect 4 so as to surround the cell region E (source electrode 3) is to form a low-resistance interconnect path, constituted of a metal such as aluminum, that also reaches the transistors distantly located from the gate bonding pad 5.

Further as shown in FIG. 5B, the gate electrodes 14, 14a constituted of polysilicon are provided in the gate trenches 11, 11a formed in a mesh pattern on a surface layer of the cell region E.

The lead structure of the gate electrodes 14, 14a will now be described, referring now to FIGS. 5B and 6A.

The gate interconnect lead 15, which serves to draw out the gate electrodes 14, 14a formed in a mesh pattern in the cell region E toward outside thereof, includes the linear lead portion 15a formed by filling with polysilicon a trench extended by a predetermined length from the gate trenches 11, 11a to outside of the cell region E, and the loop lead portion 15b constituted of polysilicon orthogonally overlapping an end portion of the linear lead portion 15a for connection thereto.

The loop lead portion 15b is provided so as to surround the cell region E (source electrode 3) with a predetermined spacing therefrom.

Thus, as shown in FIG. 6A, the gate electrodes 14, 14a and the linear lead portions 15a are integrally formed in the continuous trenches, and the loop lead portion 15b overlaps the multitude of linear lead portions 15a by a predetermined length for connection thereto, to thereby connect those linear lead portions with one another outside the cell region E.

Also, the gate interconnect lead 15 is electrically connected to the gate interconnect 4 through a contact plug (not shown) constituted of tungsten formed so as to penetrate through the interlayer dielectric (not shown) provided on the gate interconnect lead 15 (for example, refer to FIG. 23 of JP-A No. 2005-197274).

Referring further to FIG. 6B, JP-A No. 2002-373988 discloses a lead structure including a polysilicon layer P1 formed in a trench outwardly extended from an outermost peripheral gate electrode SG, a polysilicon layer P2 formed in a trench link connecting those trenches, and a gate pad P3 overlapping the polysilicon layer P2 (for example, refer to FIG. 8C of JP-A No. 2002-373988).

Lately the power MOSFET employed in a DC/DC converter and the like is required to operate at higher and higher speed, and shortening the switching time of the power MOSFET is one of indispensable measures.

For such purpose it is essential to reduce the gate resistance, and more particularly the resistance of the interconnect portion constituted of polysilicon, which has higher resistance than metals, has to be reduced. In particular, the interconnect resistance (indicated by R in FIGS. 6A and 6B) of the linear lead portion 15a according to JP-A No. 2005-197274, which is the lead portion formed in narrow trenches, as well as that of the polysilicon layer P1 according to JP-A No. 2002-373988, is beyond a negligible level.

### SUMMARY

In one embodiment, there is provided a power MOSFET comprising:

a cell region in which a plurality of cells constituted of a transistor having a gate electrode formed in a trench is aligned, the plurality of cells being arranged to form a square grid; and

a gate interconnect lead formed so as to extend out of said cell region, with an end portion overlapping an outermost peripheral gate electrode in said cell region for connection.

The power MOSFET thus constructed offers the advantage that a sufficient current path area can be secured, since the gate interconnect lead has one of its end portions overlapping an outermost peripheral gate electrode in the cell region, for connection thereto.

Thus, the power MOSFET according to the present invention allows reducing the gate resistance, and thereby shortening the switching time of the power MOSFET.

### BRIEF DESCRIPTION OF THE DRAWINGS

The above and other objects, advantages and features of the present invention will be more apparent from the following description taken in conjunction with the accompanying drawings, in which:

FIG. 1A is a plan view of a power MOSFET chip according to the present invention, and FIG. 1B is an enlarged fragmentary plan view thereof;

FIGS. 2A and 2B are detailed cross-sectional views taken along a line C-C′ and D-D′ in FIG. 1B, respectively;

FIGS. 3A and 3B are a fragmentary perspective view and a plan view respectively, schematically showing a connection arrangement of a gate electrode and a gate polysilicon interconnect according to the present invention;

FIGS. 4A to 4C are fragmentary cross-sectional views showing the progress of a manufacturing process of the power MOSFET according to the present invention;

FIG. 5A is a plan view of a conventional power MOSFET chip, and FIG. 5B is an enlarged fragmentary plan view thereof; and

FIGS. 6A and 6B are fragmentary perspective views schematically showing a connection arrangement of a gate electrode and a gate interconnect lead.

### DETAILED DESCRIPTION

The present invention will now be described herein with reference to illustrative embodiments. Those skilled in the art will recognize that many alternative embodiments can be accomplished using the teachings of the present invention and that the invention is not limited to the embodiments illustrated for explanatory purposes.

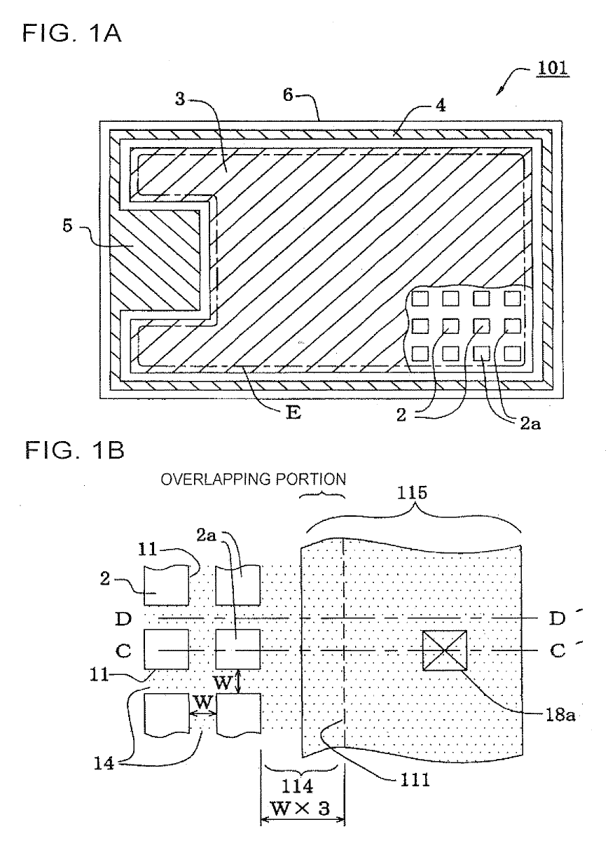

FIGS. 1A to 3B depict an example of a power MOSFET according to the present invention.

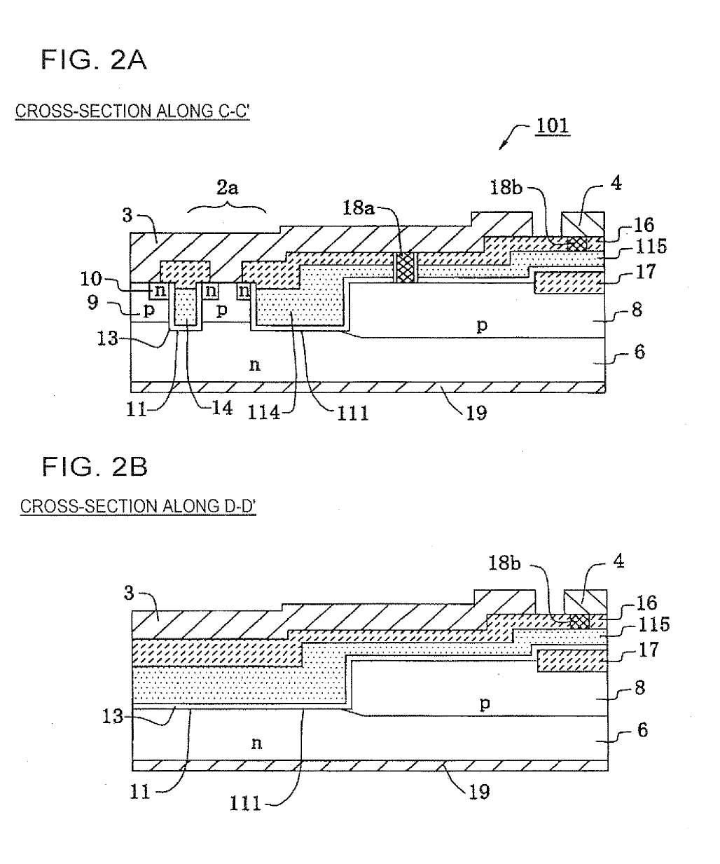

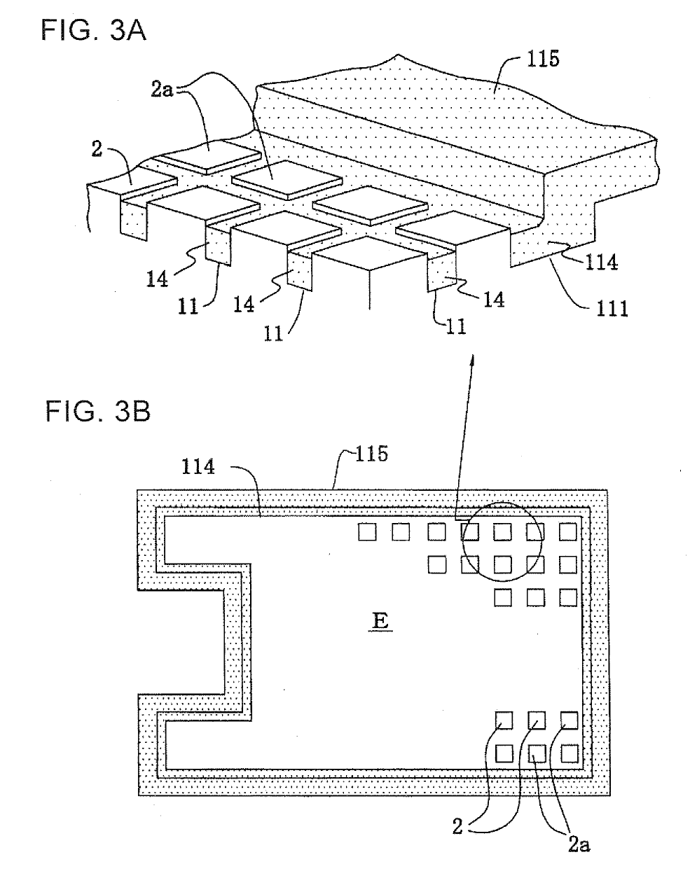

FIG. 1A is a plan view of the power MOSFET chip; FIG. 1B is an enlarged fragmentary plan view thereof; FIG. 2A is a detailed cross-sectional view taken along a line C-C′ in FIG. 1B; and FIG. 2B is a detailed cross-sectional view taken along a line D-D′ in FIG. 1B. FIGS. 3A and 3B are a fragmentary perspective view and a plan view respectively, schematically showing a connection arrangement of a gate electrode and a gate interconnect lead. Here, a source electrode, a gate insulating layer and an interlayer dielectric are excluded from FIGS. 1B and 3A.

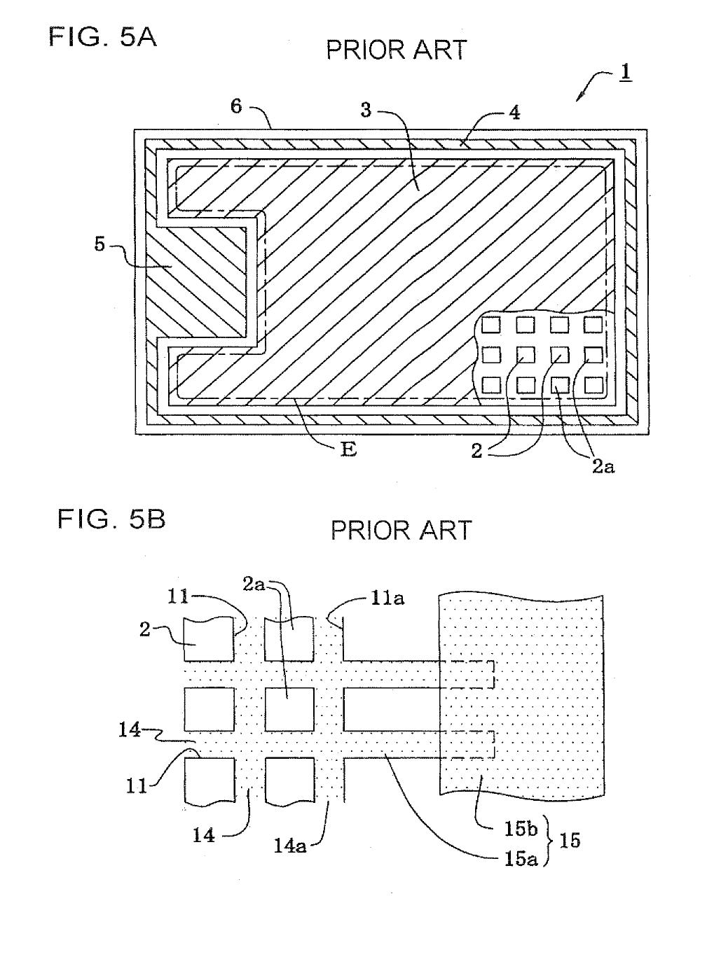

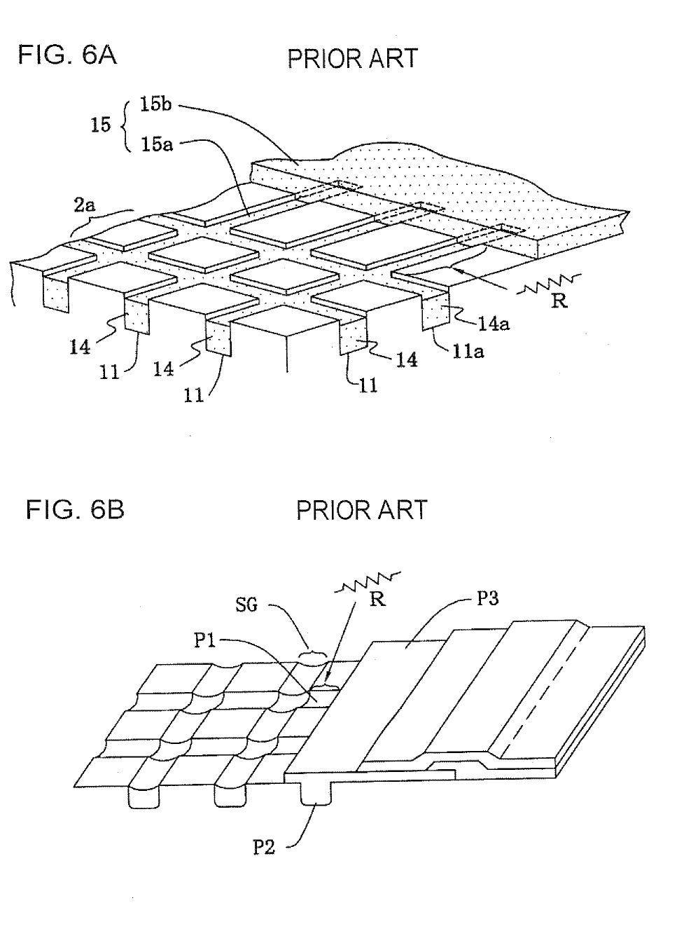

In FIGS. 1A to 3B, the numeral 101 designates the power MOSFET chip, 111 an outermost peripheral gate trench, 114 an outermost peripheral gate electrode, 115 a gate interconnect lead, and E a cell region (region enclosed by dash-dot lines in FIG. 1A). Also, the constituents in FIGS. 1A to 3B that are the same as those in FIGS. 5A to 6B are given the same numeral.

As shown in FIG. 1A, the power MOSFET chip 101 includes, on its central portion, the cell region E in which a multitude of cells 2, 2a constituted of a vertical transistor is regularly aligned.

All over the cell region E, the source electrode 3 constituted of aluminum or the like is provided, with the intermediation of the interlayer dielectric.

Outside of the cell region E (source electrode 3), the gate interconnect 4 is provided so as to surround the cell region E, with a predetermined spacing therefrom.

The gate interconnect 4 is electrically connected to the gate bonding pad 5 provided at a predetermined position.

A purpose of providing the gate interconnect 4 so as to surround the cell region E (source electrode 3) is to form a low-resistance interconnect path, constituted of a metal such as aluminum, that also reaches the transistors distantly located from the gate bonding pad 5.

Further as shown in FIG. 1B, the gate electrodes 14, 114 constituted of polysilicon are provided in the gate trenches 11, 111 formed in a mesh pattern on a surface layer of the cell region E.

Referring then to FIG. 2A, the cell 2 (FIGS. 2A and 2B only depict the vicinity of the outer peripheral cell 2a) is constituted as a vertical FET including an n-type semiconductor substrate 6 serving as a drain region, a p-type well layer 8 and a p-type base region 9 formed on a surface layer of the semiconductor substrate 6, and the gate electrodes 14, 114 constituted of an n-type source region 10 formed on a surface layer of the p-type base region 9, and polysilicon provided in the gate trenches 11, 111 with the intermediation of a gate insulating layer 13.

The p-type base region 9 is electrically connected to the source electrode 3 through an opening provided in the interlayer dielectric 16.

The p-type well layer 8 is electrically connected to the source electrode 3 through a contact plug 18a constituted of tungsten, formed in a contact hole provided through the gate insulating layer 13, the gate interconnect lead 115 and the interlayer dielectric 16. The contact plug 18a and the gate interconnect lead 115 are insulated by an insulating layer formed over the inner sidewall of the contact hole.

The lead structure of the gate electrodes 14, 114 will now be described, referring now to FIGS. 1B to 3B.

The gate interconnect lead 115, which serves to draw out the gate electrodes 14, 114, formed in a mesh pattern in the cell region E to outside thereof, is an interconnect constituted of polysilicon, with an end portion thereof overlapping the outermost peripheral gate electrode 114 in the cell region E for connection thereto, and formed so as to spread over toward outside of the cell region E.

The width of the outermost peripheral gate electrode 114 (outermost peripheral gate trench 111) is in a range of twice to five times (three times in FIG. 1B) of the width W of other gate electrodes 14 (gate trenches 11).

For example, the width of the outermost peripheral gate electrode 114 may be set as 2 to 5 μm.

Also, the gate interconnect lead 115 is formed so as to overlap the outermost peripheral gate electrode 114 by a widthwise half portion thereof.

Here, a purpose of making the outermost peripheral gate electrode 114 at least twice as wide as other gate electrodes 14 is to increase the connection area on the overlapping connection portion, to thereby secure a sufficient mechanical strength and current path area.

Also, a purpose of forming the gate interconnect lead 115 so as to overlap the outermost peripheral gate electrode 114 by a widthwise half portion thereof is to secure a margin that can absorb manufacturing fluctuation in the positioning of a resist mask in the process of forming the overlapping connection portion by an etchback process to be described later, by setting the overlapping target pine along the widthwise center of the outermost peripheral gate electrode 114, which is formed in the sufficiently width.

Further, a purpose of making the outermost peripheral gate electrode 114 not more than five times as wide as other gate electrodes 14 is to achieve desirable filling performance of the polysilicon with minimized unevenness, when filling the trench with polysilicon.

Further, providing the gate interconnect lead 115 in a spreading form so as to overlap the outermost peripheral gate electrodes 114 for connection, generally over the entire periphery thereof thus to surround the cell region E, eliminates the narrow linear lead portion 15a (FIG. 6A) or narrow linear lead portion P1 (FIG. 6B) formed in the conventional trenches, thereby allowing reducing the resistance of the polysilicon interconnect, which results in reducing the gate resistance.

In other words, as shown in FIGS. 3A and 3B, the outermost peripheral gate electrode 114 and the gate interconnect lead 115 are both constituted of polysilicon, and are continuously and integrally formed so as to overlap by a widthwise half portion of the outermost peripheral gate electrode 114.

The plurality of cells formed in the cell region E of the power MOSFET chip 101 are arranged to form a square grid, thereby each distance between an outer edge of one of the outermost peripheral cells and an inner edge of the gate interconnect lead 115 is equal to each other at any portion. Thus the interconnect resistance at a portion of the outermost peripheral gate electrode 114 is controlled to be even at any portion. Therefore, switching timing of each of the cells which is arranged in same distance from the gate interconnect lead 115 can be synchronized. That allows uniformity of heat distribution of the power MOSFET chip 101.

Also, as shown in FIGS. 2A and 2B, the interlayer dielectric 16 is provided on the gate interconnect lead 115, and through the contact plug 18b constituted of tungsten and formed so as to penetrate through the interlayer dielectric 16, the gate interconnect lead 115 is electrically connected to the gate interconnect 4.

On the upper surface side of the semiconductor substrate 6, the source electrode 3, electrically connected to the p-type base region 9 and the n-type source region 10 through an opening provided on the interlayer dielectric 16, is provided, and on the lower surface side a drain electrode 19 is provided.

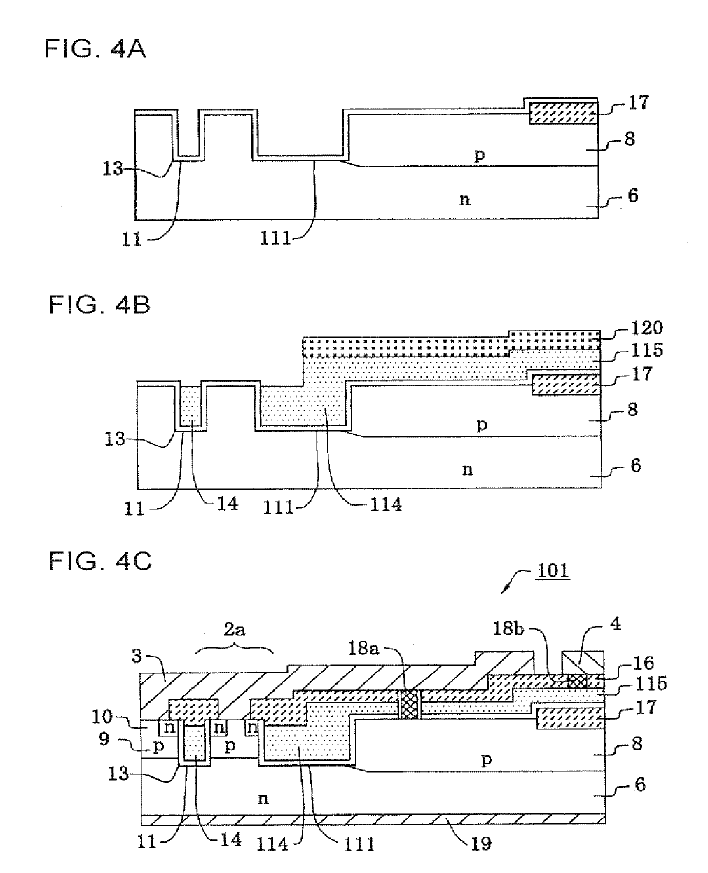

A manufacturing method of the power MOSFET chip 101 will now be described, referring to FIGS. 4A to 4C. FIGS. 4A to 4C are fragmentary cross-sectional views showing the progress of the manufacturing process of the device.

Referring first to FIG. 4A, a photolithography process is performed to selectively implant boron onto the semiconductor substrate 6, after which heat treatment is performed, to thereby form the p-type well layer 8.

Then a local oxidation of silicon (LOCOS) is performed, to thereby form a field oxidation layer 17 in a predetermined region.

The gate trenches 11, 111 are then formed through a photolithography process and a selective etching process.

In this process, the resist mask pattern is to be made such that the outermost peripheral gate trench 111 becomes twice to five times as wide as other gate trenches 11.

Thereafter, the gate insulating layer 13 is formed all over, by a thermal oxidation process.

Then referring to FIG. 4B, a CVD process is performed to form a polysilicon layer, so as to fill in the gate trenches 11, 111.

In this process, since the outermost peripheral gate trench 111 is made not more than five times as wide as other gate trenches 11, the inside of the outermost peripheral gate trench 111 is desirably filled with the polysilicon layer.

A resist mask 120 is then prepared, and a RIE etchback process is performed.

Here, the resist mask 120 is to be made in a mat type pattern that covers a widthwise half portion of the outermost peripheral gate trench 111.

Also, the resist mask 120 is to be made in a pattern that overlaps the outermost peripheral gate trench 111 generally over the entire periphery thereof, so as to surround the cell region E.

As a result of the foregoing etchback process, regarding the gate trenches 11, the polysilicon layer remains inside thereof only.

Regarding the outermost peripheral gate trench 111, however, the polysilicon layer remains inside thereof, and besides the gate interconnect lead 115 is formed so as to spread over toward the outside of the cell region E (to the left in FIG. 4B), and to overlap the widthwise half portion of the remaining polysilicon layer, for connection thereto.

Also, overlapping the resist mask 120 on the outermost peripheral gate trench 111 targeting at the widthwise center thereof provides the advantage that, as described above, a margin for absorbing fluctuation in the positioning of the resist mask 120 can be secured. In other words, even though some manufacturing fluctuation takes place in the positioning of the resist mask, there is no likelihood that the gate interconnect lead 115 is formed beyond the outermost peripheral gate trench 111 into the diffusion region in the cell region E.

Referring finally to FIG. 4C, after removal of the resist mask 120 and ion implantation of boron, heat treatment is performed so as to form the p-type base region 9, and further ion implantation of arsenic is performed, which is followed by heat treatment to thereby form the n-type source region 10.

A CVD process is then performed so as to form the interlayer dielectric 16.

A contact hole is formed through the interlayer dielectric 16, and the hole is filled with tungsten to thereby form the contact plug 18b.

Also, an opening is formed through the interlayer dielectric 16 at a predetermined position so as to expose the p-type base region 9, and also a contact hole is formed through the gate insulating layer 13, the gate interconnect lead 115 and the interlayer dielectric 16, and the insulating layer is formed over the inner sidewall of the contact hole, which is then filled with tungsten to thereby form the contact plug 18a.

Then a sputtering process is performed so as to deposit aluminum or the like thus to form the source electrode 3 and the gate interconnect 4 on the upper surface side, so that the gate interconnect lead 115 is electrically connected to the gate interconnect 4, and the p-type base region 9, the n-type source region 10, and the p-type well layer 8 to the source electrode 3, respectively. Then a drain electrode 19 is formed on the lower surface side of the semiconductor substrate 6.

Although the gate interconnect lead 115 is formed in a mat shape spreading over so as to surround the cell region E in the foregoing embodiment, the present invention is not limited to such form.

Although the gate interconnect lead 115 and the gate bonding pad appear to be separately formed according to FIG. 3B, these may be integrally formed.

Also, though the p-type well layer 8 and the source electrode 3 are electrically connected through the contact plug 18a in the foregoing embodiment, the p-type well layer 8 may be formed in a floating configuration.

Further, although the foregoing embodiment represents the example of the n-channel MOSFET, the MOSFET may be of the p-channel type. In this case, all the conductivity types of the diffusion layer are to be opposite.

It is apparent that the present invention is not limited to the above embodiment, and may be modified and changed without departing from the scope and spirit of the invention.

What is claimed is:

1. A power MOSFET comprising:
a cell region in which a plurality of cells constituted of a transistor having a gate electrode formed in a trench is aligned, the plurality of cells being arranged to form a square grid; and
a gate interconnect lead formed so as to extend out of said cell region, with an end portion overlapping an outermost peripheral gate electrode in said cell region for connection.

2. The power MOSFET according to claim 1, wherein said gate interconnect lead is formed so as to surround said cell region.

3. The power MOSFET according to claim 1, wherein said gate interconnect lead overlaps said outermost peripheral gate electrode for connection, by generally a widthwise half portion of said outermost peripheral gate electrode.

4. The power MOSFET according to claim 1, wherein said outermost peripheral gate electrode and said gate interconnect lead are of a same type conductor.

5. The power MOSFET according to claim 1, wherein a width of said outermost peripheral gate electrode is in a range of twice to five times of that of other gate electrodes.

6. The power MOSFET according to claim 5, wherein a width of said outermost peripheral gate electrode is in a range of 2 to 5 μm.
